(19) United States
(12) Patent Application Publication
(10) Pub. No.: US 2007/0164415 A1
(43) Pub. Date: Jul. 19, 2007

(54) Semiconductor device including bus with signal lines

(75) Inventor: Jun Setogawa, Tokyo (JP)

Correspondence Address: BUCHANAN, INGERSOLL & ROONEY PC, POST OFFICE BOX 1404, ALEXANDRIA, VA, 22313-1404, US

(73) Assignee: Renesas Technology Corp., Tokyo (JP)

(21) Appl. No.: 11/651,532

(22) Filed: Jan. 10, 2007

(30) Foreign Application Priority Data
Jan. 13, 2006 (JP) 2006-006388

(51) Int. Cl. H01L 23/02

(52) U.S. Cl. 257/679

(57) ABSTRACT

A semiconductor memory device has the group of longest signal lines configured in a twisted wiring scheme, the group of signal lines of intermediate length configured in a shield wiring scheme, and the group of shortest signal lines configured in a single wiring scheme. As a whole, degradation in signal waveform and improvement in layout efficiency can both be achieved.

### BACKGROUND OF THE INVENTION

1. Field of the Invention

The present invention relates to semiconductor devices, particularly a semiconductor device including a bus formed of a plurality of signal lines.

2. Description of the Background Art

Conventionally, a semiconductor memory device is provided with a data bus for transmitting data signals of a plurality (for example 4, 8, 16) of bits (refer to, Japanese Patent Laying-Open No. 2001-076490, for example). The data bus includes a plurality of signal lines for transmitting a plurality of data signals. The plurality of signal lines are formed under the same wiring scheme to eliminate difference in characteristics between data signals.

In order to increase the amount of information and also the speed of transmitting information, development of increasing the bus width (increasing the number of signal lines) and dedicated wiring for signal lines is now in progress. This has induced the concern of increase in the area of the wiring region as well as variation in the characteristics between signals.

### SUMMARY OF THE INVENTION

In view of the foregoing, an object of the present invention is to provide a semiconductor device having a small area for the wiring region and minor variation in characteristics between signals.

According to an aspect of the present invention, a semiconductor device includes a bus formed of a plurality of signal lines. The plurality of signal lines are configured in a plurality of wiring schemes. By configuring a short signal line in the single wiring scheme and a long signal line in a shield wiring scheme or twisted wiring scheme, a semiconductor device having a small area for the wiring region and minor variation in characteristics between signals can be realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 represents a layout of a semiconductor memory device according to an embodiment of the present invention.

FIG. 2 is a diagram to describe the twisted wiring scheme shown in FIG. 1.

FIGS. 3A-3D are waveform diagrams of signals transmitted by the signal lines of FIG. 2.

FIG. 4 is a diagram to describe the shield wiring scheme shown in FIG. 1.

FIGS. 5A-5D are waveform diagrams of signals transmitted by the signal lines of FIG. 4.

FIG. 6 is a diagram to describe the single wiring scheme shown in FIG. 1.

FIGS. 7A-7D are waveform diagrams of signals transmitted by the signal lines shown in FIG. 6.

### DESCRIPTION OF THE PREFERRED EMBODIMENT

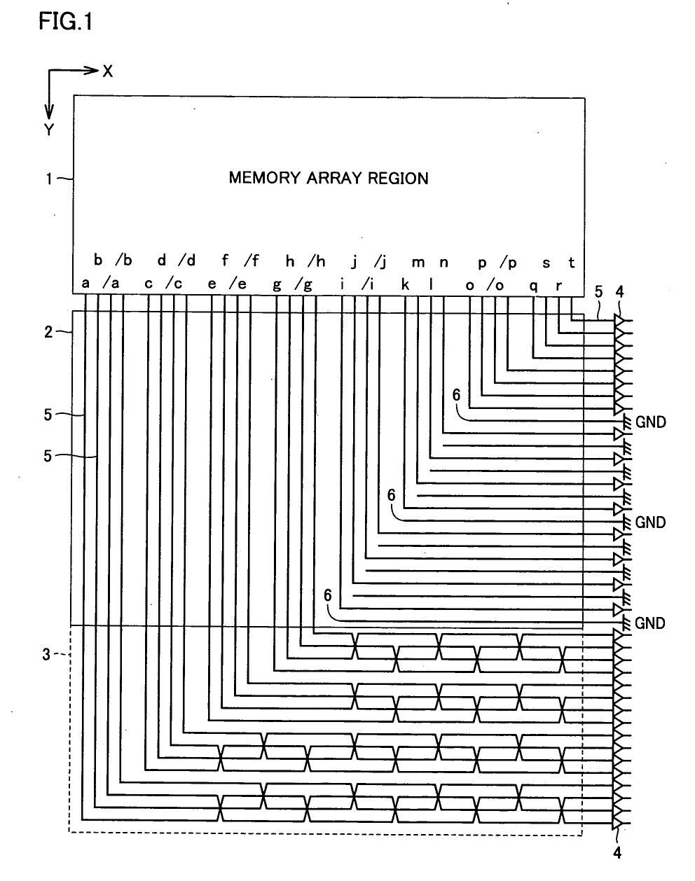

Referring to FIG. 1, a semiconductor memory device according to an embodiment of the present invention is formed in a rectangular region at the surface of a semiconductor substrate. The rectangular region is divided into a memory array region 1, a circuit region 2, and a wiring region 3, from the top to the bottom in the drawing. A plurality (32 in the drawing) of output circuits 4 are arranged along the right side of circuit region 2 and wiring region 3 in FIG. 1. Memory array region 1 has its bottom side in the drawing connected to the input nodes of output circuits 4 through respective (32 in the drawing) signal lines 5.

A plurality of memory cells, a plurality of sense amplifiers, a plurality of column select gates, and the like are provided in memory array region 1. The plurality of memory cells are arranged in a matrix. Data is stored in each memory cell. Each memory cell has a unique address assigned. A sense amplifier is provided corresponding to each column, for example, to amplify a data signal read out from the memory cell in a selected row of a corresponding column. A column select gate is provided corresponding to a predetermined number of sense amplifiers, for example, and connects a sense amplifier of the selected column among the plurality of sense amplifiers to a corresponding signal line 5. It is assumed that twenty-four complementary data signals a, /a; . . . ; p, /p and eight non-complementary signals k-t are output from the bottom side of memory array region 1 to respective one ends of 32 signal lines 5.

In circuit region 2 are provided a row decoder selecting a memory cell row among a plurality of memory cell rows according to a row address signal, a column decoder selecting a memory cell column among a plurality of memory cell columns according to a column address signal, a control circuit controlling the entirety of the semiconductor memory device, and the like.

The 32 signals a, /a; . . . ; p, /p and k-t output from the bottom side of memory array region 1 are divided in groups of 4. The 32 signal lines 5 are divided in groups of 4. The 32 output circuits are also divided in groups of 4. The group of signals (a, b, /a, /b) at the left side in FIG. 1 is input to the group of output circuits 4 at the bottom side in the drawing via the group of signal lines 5 passing the left side and bottom side in the drawing. The group of signals (q, s, r, t) at the right side in the drawing is input to the group of output circuits 4 at the upper side in the drawing via the group of signal lines 5 passing through the right side and upper side in the drawing. Accordingly, signal lines 5 corresponding to the left side signal group (a, b, /a, /b) are longest and signal lines 5 corresponding to the right side signal group (q, s, r, t) are shortest.

In this semiconductor memory device, the wiring scheme is altered according to the length of signal line 5 in consideration of the balance between degradation in the signal waveform and layout efficiency. In other words, the group of longest signal lines 5 is configured in a twisted wiring scheme to avoid degradation in the signal waveform. The group of signal lines 5 of intermediate length is configured in the shield wiring scheme to reduce degradation in the signal waveform and improve the layout efficiency to a certain degree. The group of shortest signal lines 5 is configured in the single wiring scheme of high layout efficiency.

Specifically, 16 signal lines 5 transmitting signals a, /a; . . . ; h, /h among the 32 signal lines 5 extend downwards (Y direction) in the drawing, running above circuit region 2, then bent rightwards (X direction) in wiring region 3, and twisted for every 4 lines to be connected to the 16 corresponding output circuits 4.

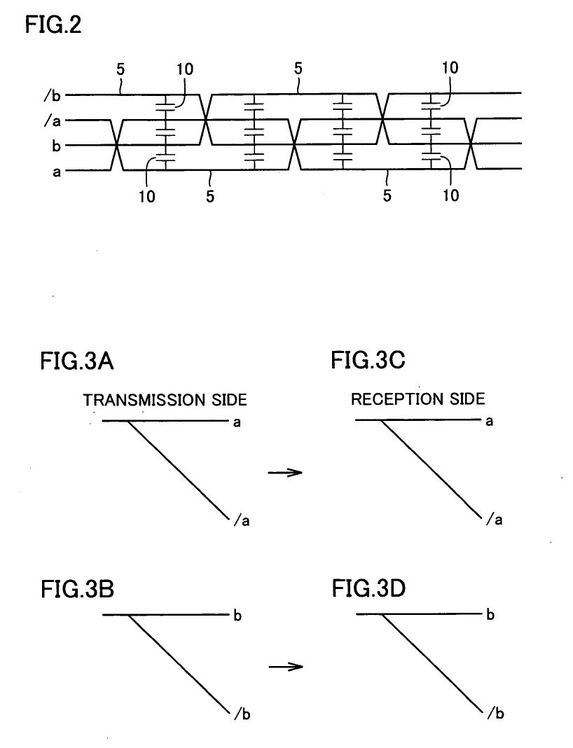

FIG. 2 represents the twisted portion of the four signal lines 5 corresponding to signals a, /a; b, /b. Signals a, b, /a and /b are input to respective one ends of four adjacent signal lines 5. The first and third signal lines 5 corresponding to signals a and /a are twisted at a predetermined pitch. The second and fourth signal lines 5 corresponding to signals b and /b are twisted at a predetermined pitch. The crossing between the first and third signal lines 5 deviates from the crossing between the second and fourth signal lines 5 by half a pitch.

Since there is parasitic capacitance (indicated by capacitor 10 in FIG. 2) between each two adjacent signal line portions, the change in potential of one signal line portion is transmitted to the other signal line portion by capacitive coupling. However, the effect of capacitive coupling is canceled by twisting signal lines 5 together, so that there is almost no effect of capacitive coupling on signal line 5. This will be described with reference to FIGS. 3A-3D. FIGS. 3A and 3B represent the waveform of signals a, /a; b, /b transmitted from memory array region 1. FIGS. 3C and 3D represent waveforms of signals a, /a; b, /b received at output circuits 4. FIGS. 3A and 3B represent the case where signals a and b are maintained at an H level (logical high), and signals /a and /b are pulled down from an H level to an L level (logical low) at a certain time, at the transmission side (memory array region 1 side). Since there is almost no effect of capacitive coupling on signal line 5 in the twisted wiring scheme, the signal waveform at the reception side (output circuit 4 side) hardly differs from the signal waveform at the transmission side (memory array region 1 side), as shown in FIGS. 3C and 3D. It is to be noted that a plurality of metal interconnection layers are required to twist signal lines 5 together in such a twisted wiring scheme. A dedicated wiring region 3 is required since it is difficult to twist the signal lines above circuit region 2. Therefore, in the twisted wiring scheme, the layout efficiency is degraded although degradation in signal waveform can be prevented. The same applies to signal lines 5 corresponding to signals c, /c; . . . ; h, /h.

Furthermore, eight signal lines 5 transmitting signals i, /i; j, /j; k-n among the thirty-two signal lines 5 extend in the Y direction in the drawing, running above circuit region 2, and then bent in the X direction to be connected to the input nodes of the eight corresponding output circuits 4. At the region of the eight signal lines 5 extending in the X direction in the drawing, a shield line 6 is provided at either side of and between these eight signal lines 6. Ground voltage GND is applied to each shield line 6.

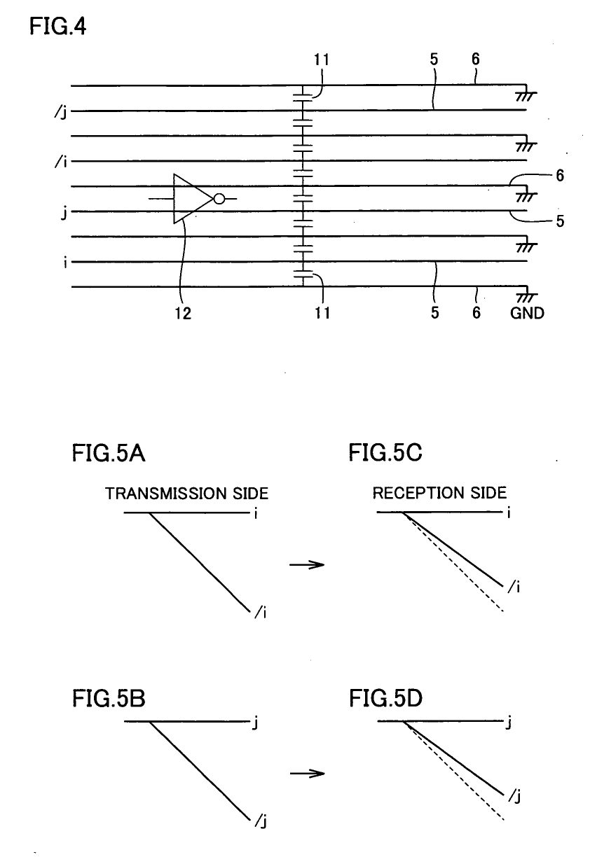

FIG. 4 represents the portion of four signal lines 5 corresponding to signals i, /i; j, /j, extending in the X direction. Signals i, j, /i, /j are input to respective one ends of the four adjacent signal lines 5. A shield line 6 is arranged between each of the four signal lines 5, i.e. a total of five shield lines 6 is arranged. Parasitic capacitance (indicated by capacitor 11 in FIG. 4) is present between each signal line 5 and an adjacent shield line 6. Signal line 5 and shield line 6 are formed of a unitary metal interconnection layer, provided above the circuit (indicated by inverter 12 in FIG. 4) in circuit region 2.

According to such a shield wiring scheme, the capacitive coupling between signal lines 5 can be reduced by virtue of shield line 6, without having to provide a dedicated wiring region. However, the effect of capacitive coupling between signal lines 5 cannot be eliminated as in the twisted wiring scheme. This will be described with reference to FIGS. 5A-5D. FIGS. 5A and 5B represent the waveform of signals i, /i; j, /j transmitted from memory array region 1. FIGS. 5C and 5D represent the waveform of signals i, /i; j, /j received at output circuits 4. FIGS. 5A and 5B represent the case where signals i and j are maintained at an H level, and signals /i, /j are pulled down from an H level to an L level at a certain time, at the transmission side (memory array region 1 side). Since the effect of capacitive coupling on signal lines 5 can be reduced, but not completely eliminated in the shield wiring scheme, the signal waveform at the reception side (output circuit 4 side) is slightly inferior to the signal waveform at the transmission side (memory array region 1 side), and the fall of signals /i and /j is delayed, as shown in FIGS. 5C and 5D. In addition, the layout area is increased corresponding to shield lines 6. The same applies to signal lines 5 corresponding to signals k-n.

Further, eight signal lines 5 transmitting signals o, /o; p, /p; q-t among the thirty-two signal lines 5 extend in the Y direction in the drawing, running above circuit region 2, and then bent in the X direction to be connected to respective input nodes of the eight corresponding output circuits 4.

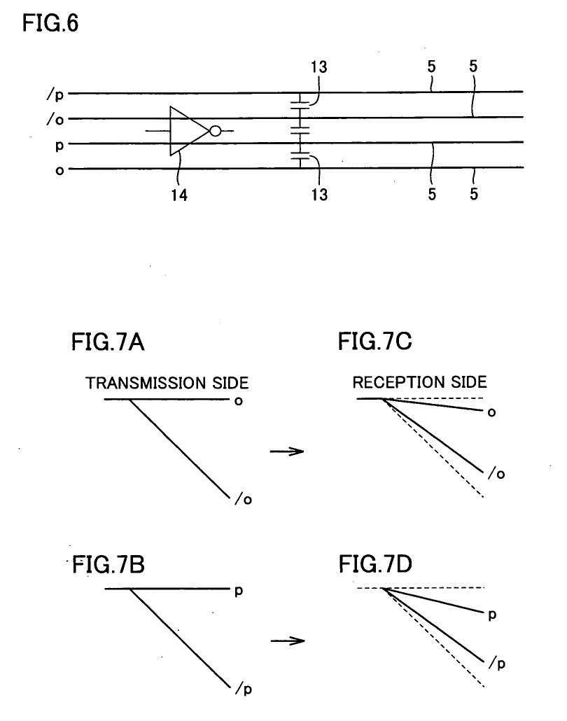

FIG. 6 represents the portion of the four signal lines 5 corresponding to signals o, /o; p, /p, extending in the X direction in the drawing. Parasitic capacitance (indicated by capacitor 13 in FIG. 4) is present between two adjacent signal lines 5. Signal line 5 is formed of a unitary metal interconnection layer, and provided above the circuit (indicated by inverter 14 in FIG. 4) in circuit region 2.

In such a single wiring scheme, a dedicated wiring region is not required since signal lines 5 do not have to be twisted. Further, the layout efficiency is high since signal lines 5 can be arranged above circuit region 2, and a shield line 6 is not provided between signal lines 5. However, the effect of capacitive coupling between signal lines 5 becomes greater as compared to the twisted wiring scheme and shield wiring scheme. This will be described with reference to FIGS. 7A-7D. FIGS. 7A and 7B represent the waveform of signals o, /o; p, /p transmitted from memory array region 1. FIGS. 7C and 7D represent waveforms of signals o, /o; p, /p received at output circuits 4. FIGS. 7A and 7B represent the case where signals o and p are maintained at an H level, and signals /o and /p are pulled down from an H level to an L level at a certain time, at the transmission side (memory array region 1 side). Since the effect of capacitive coupling on signal lines 5 becomes greater in the single wiring scheme, the signal waveform at the reception side (output circuit 4 side) is greatly inferior to the signal waveform at the transmission side (memory array region 1 side), as shown in FIGS. 7C and 7D. Furthermore, the fall of signals /o and /p is delayed and the level of signals o and p are also reduced in accordance with the fall of signals /o and /p. The same applies to signal lines 5 corresponding to signals q-t.

In the present embodiment, the group of the longest signal lines 5 is formed in the twisted wiring scheme; the group of signal lines 5 of the intermediate length is formed in the shield wiring scheme; and the group of the shortest signal lines 5 is formed in the single wiring scheme. As a whole, degradation in signal waveform and improvement of layout efficiency can both be achieved. A semiconductor memory device having a small area of the wiring region, and minor variation in characteristics between signals can be realized.

Although the length of signal lines 5 is divided into three stages in the present embodiment, the length of signal lines 5 can be divided into two stages, wherein the group of shorter signal lines 5 is configured in the single wiring scheme, and the group of the longer signal lines 5 is configured in the shield wiring scheme. Alternatively, the group of shorter signal lines 5 may be configured in the single wiring scheme whereas the group of the longer signal lines 5 may configured in the twisted wiring scheme. Further alternatively, the group of shorter signal lines 5 may be configured in the shield wiring scheme whereas the group of the longer signal lines 5 may be configured in the twisted wiring scheme.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device including a bus formed of a plurality of signal lines, said plurality of signals lines configured in a plurality of wiring schemes.

2. The semiconductor device according to claim 1, wherein
said plurality of signal lines differ in length, and
the wiring scheme of each signal line is determined according to the length of the signal line.

3. The semiconductor device according to claim 1, wherein said plurality of wiring schemes include at least two wiring schemes among three wiring schemes corresponding to a twisted wiring scheme of twisting each signal line with another signal line, a shield wiring scheme of arranging a shield line between two adjacent signal lines, and a single wiring scheme of not twisting signal lines together and not arranging a shield line.

4. The semiconductor device according to claim 3, wherein
said plurality of signal lines include a first signal line, and a signal second signal line longer than said first signal line,
said first signal line is configured in said single wiring scheme, and
said second signal line is configured in said shield wiring scheme or said twisted wiring scheme.

5. The semiconductor device according to claim 3, wherein
said plurality of signal lines include a first signal line and a second signal line longer than said first signal line,
said first signal line is configured in said shield wiring scheme, and
said second signal line is configured in said twisted wiring scheme.

6. The semiconductor device according to claim 3, wherein
said plurality of signal lines includes a first signal line, a second signal line longer than said first signal line, and a third signal line longer than said second signal line,
said first signal line is configured in said single wiring scheme,
said second signal line is configured in said shield wiring scheme,
said third signal line is configured in said twisted wiring scheme.
